(19) United States
(12) Patent Application Publication
(10) Pub. No.: US 2026/0059960 A1
(43) Pub. Date: Feb. 26, 2026

(54) TRANSPARENT DISPLAY APPARATUS

(71) Applicant: LG Display Co., Ltd., Seoul (KR)

(72) Inventors: Binn KIM, Paju-si (KR); Dojin KIM, Paju-si (KR)

(73) Assignee: LG Display Co., Ltd., Seoul (KR)

(21) Appl. No.: 19/276,875

(22) Filed: Jul. 22, 2025

(30) Foreign Application Priority Data
Aug. 22, 2024 (KR) 10-2024-0113109

(51) Int. Cl. H10K 59/35; H10K 59/80

(52) U.S. Cl. CPC H10K 59/353; H10K 59/8792

(57) ABSTRACT

A transparent display apparatus according to some examples of the present disclosure includes a substrate provided with a plurality of pixels each having a plurality of sub-pixels, a transmissive area provided on the substrate and arranged adjacent to at least some subpixels among the plurality of subpixels, and a color pattern portion partially overlapping the transmissive area.

### CROSS-REFERENCE TO RELATED APPLICATIONS

This application claims priority to Korean Patent Applications No. 10-2024-0113109 filed in the Republic of Korea on Aug. 22, 2024, the entire contents of which are hereby expressly incorporated by reference into the present application.

### BACKGROUND

### Technical Field

The present disclosure relates to a transparent display apparatus.

### Discussion of the Related Art

With the advancement of the information age, the demand for a display apparatus for displaying an image has increased in various forms. Therefore, various types of display apparatuses such as a liquid crystal display (LCD) apparatus, a plasma display panel (PDP) apparatus, an organic light emitting display (OLED) apparatus and a quantum dot light emitting display (QLED) apparatus have been recently used.

Recently, studies for a transparent display apparatus in which a user can view objects or images positioned at an opposing side by transmitting the display apparatus are actively ongoing.

A transparent display apparatus can include a display area, on which an image is displayed, in a substrate, and the display area can include a transmissive area capable of transmitting external light and a non-transmissive area that does not transmit light. The non-transmissive area can include a plurality of light emission areas in which light is emitted, and a non-light emission area provided between the plurality of the light emission areas. An organic light-emitting layer and an opposing electrode can be arranged in the plurality of light emission areas.

Meanwhile, in order to reduce the manufacturing process steps of the transparent display apparatus, the organic light-emitting layer and/or the opposing electrode can be placed in a transmissive area as well. However, such organic light-emitting layer and/or the opposing electrode has a low transmittance for short wavelengths. Therefore, the transparent display apparatus can have a limitation in that the color of the background and/or object seen through the transmissive area can be yellowish due to the organic light-emitting layer and/or the opposing electrode disposed in the transmissive area.

### SUMMARY OF THE DISCLOSURE

The present disclosure is to provide a transparent display apparatus in which yellowish color of a background and/or an object can be minimized or prevented.

The present disclosure is to provide a transparent display apparatus capable of improving clarity.

The present disclosure is to provide a transparent display apparatus in which the overall power consumption can be reduced or minimized.

The technical benefits of the present disclosure are not limited to the above-mentioned benefits, and other benefits, which are not mentioned above, can be clearly understood by those skilled in the art from the following descriptions.

A transparent display apparatus according to one or more embodiments of the present disclosure can include a substrate provided with a plurality of pixels each having a plurality of sub-pixels, a transmissive area provided on the substrate and arranged adjacent to at least some subpixels among the plurality of subpixels, and a color pattern portion partially overlapping the transmissive area.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a transparent display apparatus according to one or more embodiments of the present disclosure.

FIG. 2 is a schematic enlargement of portion A of FIG. 1, showing a single pixel.

FIG. 3 is a schematic cross-sectional view of the line I-I′ shown in FIG. 2.

FIG. 4 is a schematic cross-sectional view of the line II-II′ shown in FIG. 2.

FIG. 5 is a schematic graph showing color sensation according to the ratio of a color pattern portion overlapping a transmissive area of a transparent display apparatus according to one embodiment of the present disclosure.

FIG. 6 is a schematic graph showing a transmittance of a transmissive area according to the thickness of a color pattern portion overlapping a transmissive area of a transparent display apparatus according to one embodiment of the present disclosure.

FIG. 7 is a schematic cross-sectional view of the line III-III′ shown in FIG. 2.

FIG. 8 is a schematic plan view showing the distance between a center of a transmissive area and a color pattern portion of a transparent display apparatus according to one embodiment of the present disclosure.

FIG. 9 is a plan view showing another example of a color pattern portion of a transparent display apparatus according to one embodiment of the present disclosure.

FIG. 10 is a cross-sectional view showing a transparent display apparatus according to another embodiment of the present disclosure.

FIG. 11 is a plan view showing a transparent display apparatus according to another embodiment of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part can be added unless ‘only’ is used. The terms of a singular form can include plural forms unless referred to the contrary. In construing an element, the element is construed as including an error range although there is no explicit description.

In describing a position relationship, for example, when a position relation between two parts is described as ‘on’, ‘over’, ‘under’, ‘below’, ‘next’, etc., one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used. It will be understood that, although the terms “first,” “second,” etc. can be used herein to describe various elements, these elements should not be limited by these terms.

These terms are only used to distinguish one element from another. For example, a first element could be termed a second element, and, similarly, a second element could be termed a first element, without departing from the scope of the present disclosure.

Further, “X-axis direction”, “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item. Also, the term “can” fully encompasses all the meanings and coverages of the term “may”and vice versa.

Features of various embodiments of the present disclosure can be partially or overall coupled to or combined with each other and can be variously inter-operated with each other and driven technically as those skilled in the art can sufficiently understand.

The embodiments of the present disclosure can be carried out independently from each other or can be carried out together in co-dependent relationship.

Hereinafter, the various embodiments of the present disclosure will be described in detail with reference to the accompanying drawings. All the components of each display apparatus according to all embodiments of the present disclosure are operatively coupled and configured.

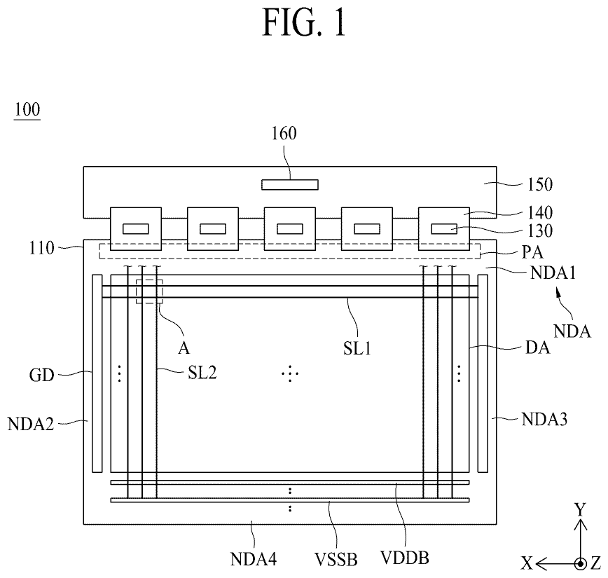

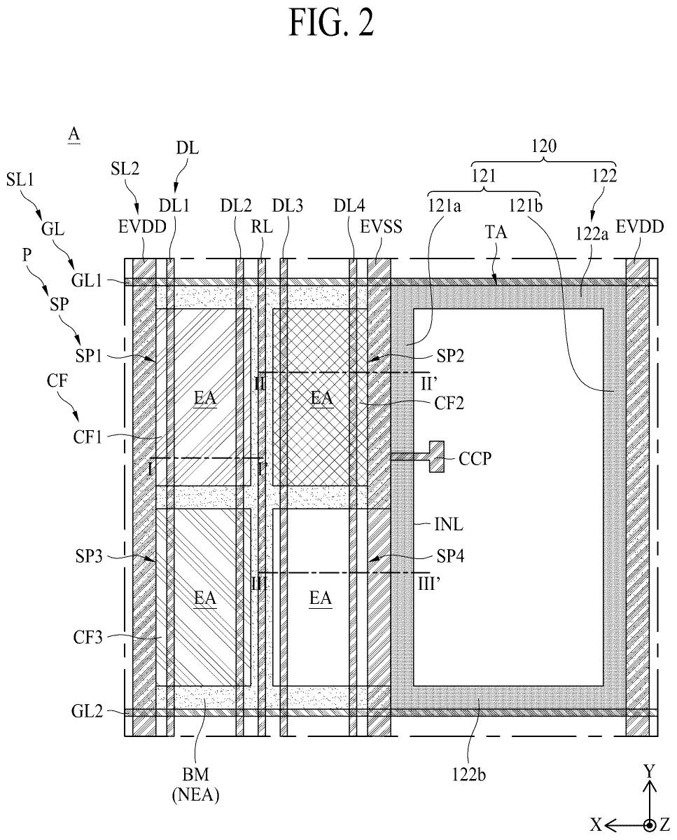

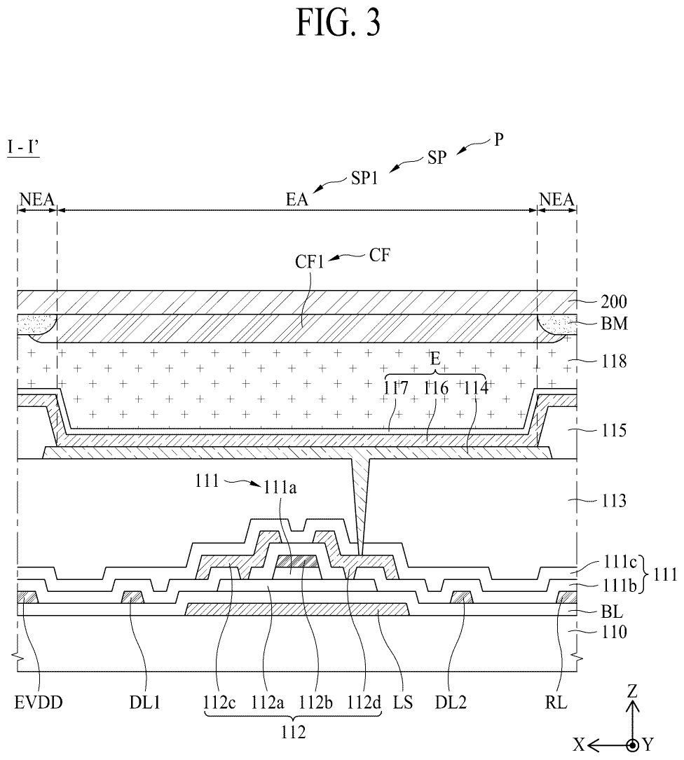

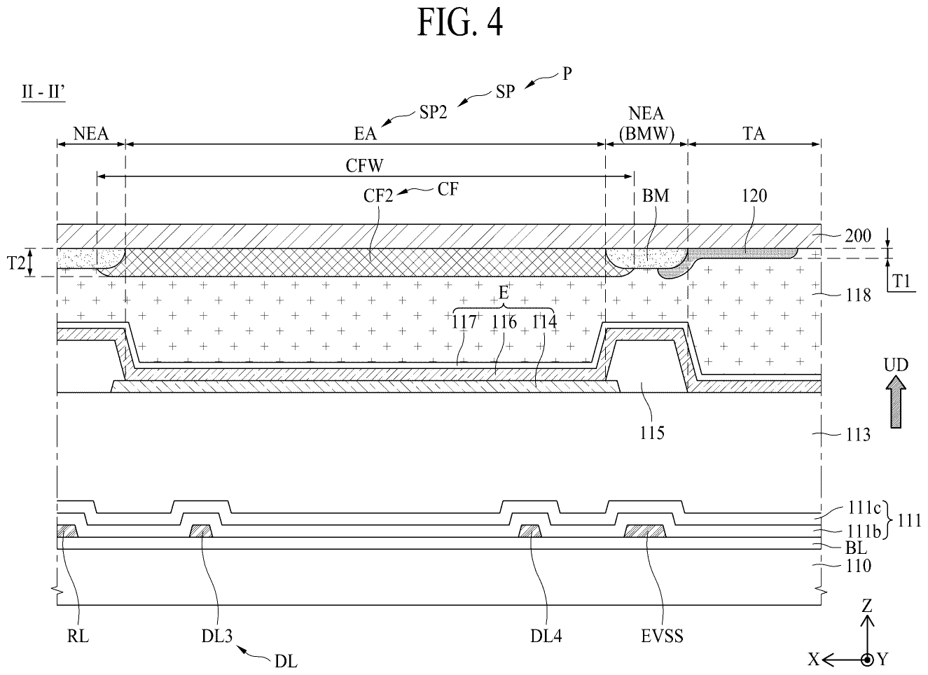

FIG. 1 is a plan view illustrating a transparent display apparatus according to one or more embodiments of the present disclosure, FIG. 2 is a schematic enlargement of portion A of FIG. 1, showing a single pixel, FIG. 3 is a schematic cross-sectional view of the line I-I′ shown in FIG. 2, and FIG. 4 is a schematic cross-sectional view of the line II-II′ shown in FIG. 2.

Hereinafter, a first direction (e.g., X-axis direction) indicates a direction parallel to a gate line GL, a second direction (e.g., Y-axis direction) indicates a direction parallel to a data line DL, and a third direction (Z-axis direction) indicates a thickness direction of the transparent display apparatus 100. These are mere examples and other variations are possible.

The following description will be based on that a transparent display apparatus 100 according to one or more embodiments of the present disclosure is an organic light emitting display apparatus, but is not limited thereto. For example, the transparent display apparatus according to one or more embodiments of the present disclosure can be implemented as any one of a liquid crystal display apparatus, a field emission display apparatus, a quantum dot lighting emitting diode apparatus, and an electrophoretic display apparatus as well as the organic light emitting display apparatus.

Referring to FIGS. 1 to 3, the transparent display apparatus 100 according to one or more embodiments of the present disclosure can include a display panel having a gate driver GD, a source drive integrated circuit (hereinafter, referred to as “IC”) 130, a flexible film 140, a circuit board 150, and a timing controller 160.

The display panel can include a substrate 110 and an opposing substrate 200 (shown in FIG. 3), which can bonded to each other or otherwise coupled to each other.

The substrate 110 can include a plurality of thin film transistors, and can be a transistor array substrate, a lower substrate, a base substrate, or a first substrate. The substrate 110 can be a transparent glass substrate or a transparent plastic substrate.

The opposing substrate 200 can be bonded to the substrate 110 via an adhesive member. For example, the opposing substrate 200 can have a size smaller than that of the substrate 110, and can be bonded to the remaining portion except the pad area of the substrate 110. Therefore, the opposing substrate 200 can be placed on the substrate 110. The opposing substrate 200 can be an upper substrate, a second substrate, or an encapsulation substrate.

The gate driver GD supplies gate signals to the gate lines in accordance with the gate control signal input from the timing controller 160. When the source drive IC 130 is manufactured as a driving chip, the source drive IC 130 can be packaged in the flexible film 140 in a chip on film (COF) method or a chip on plastic (COP) method.

Pads such as power pads and data pads can be formed in a non-display area of a display panel. A flexible film 140 can include lines connecting the pads to a source drive IC 130 and lines connecting the pads to lines of a circuit board 150. The flexible film 140 can be attached to the pads by using an anisotropic conducting film, whereby the pads can be connected to the lines of the flexible film 140.

Referring to FIG. 1, the substrate 110 according to an example can include a display area DA and a non-display area NDA.

The display area DA is an area where an image is displayed, and can be a pixel array area, an active area, a pixel array unit, a display unit, or a screen. For example, the display area DA can be disposed at a central portion of the display panel. The non-display area NDA can surround the display area DA entirely or only in part(s) thereof.

The display area DA according to an example can include gate lines, data lines, pixel driving power lines, and a plurality of pixels P (shown in FIG. 2). Each of the plurality of pixels P can include a plurality of sub-pixels SP that can be defined by the gate lines and the data lines, and a transmissive area TA provided on the substrate 110 and arranged adjacent to at least some subpixels SP among the plurality of subpixels SP. The transmissive area TA is an area provided to allow light to transmit front and rear surfaces of the display panel. Therefore, a user located in the direction of the front surface of the display panel can view a backgrounds, an objects, and an images positioned in the direction of the rear surface of the display panel through the transmissive area TA.

Each of the plurality of sub-pixels SP can be defined as a minimum unit area in which light is actually emitted.

According to one example, at least four sub-pixels, which are provided to emit light of different colors and disposed to be adjacent to one another, among the plurality of sub-pixels SP, and one transmissive area TA constitute one unit pixel P. Each of one sub-pixel SP and one transmissive area TA included in the unit pixel can be disposed to be divided into a plurality of parts. One unit pixel can include, but is not limited to, a red sub-pixel, a green sub-pixel, a blue sub-pixel, a white sub-pixel and a transmissive area TA. According to another example, three sub-pixels SP, which are provided to emit light of different colors and disposed to be adjacent to one another, among the plurality of sub-pixels SP, and one transmissive area TA constitute one unit pixel. One unit pixel can include at least one red sub-pixel, at least one green sub-pixel, at least one blue sub-pixel and one transmissive area TA, but is not limited thereto.

Each of the plurality of sub-pixels SP can include a thin film transistor and a light emitting element connected to the thin film transistor. The sub-pixel can include a light emitting layer (or an organic light emitting layer) interposed between a first electrode and a second electrode.

The light emitting layer disposed in each of the plurality of sub-pixels SP can individually emit light of different colors, or can commonly emit white light. According to one example, when the light emitting layer of each of the plurality of sub-pixels SP commonly emits white light, each of the red sub-pixel, the green sub-pixel and the blue sub-pixel can include a color filter (or a wavelength conversion member) for converting the white light into light of different colors. In this case, the white sub-pixel according to one example may not include a color filter. The color filter CF, according to one example, can include a blue color filter CF1, a red color filter CF2, and a green color filter CF3.

A transparent display apparatus 100 according to one embodiment of the present disclosure can include a colored subpixel and a white subpixel SP4 arranged adjacent to the colored subpixel. For example, the colored subpixel can include a blue subpixel SP1, a red subpixel SP2, and a green subpixel SP3. As shown in FIG. 2, the white subpixel SP4 can be arranged adjacent to each of the blue subpixel SP1, the red subpixel SP2, and the green subpixel SP3.

In the transparent display apparatus 100 according to one embodiment of the present disclosure, an area in which a blue color filter CF1 is provided can be a blue sub-pixel SP1, an area in which a red color filter CF2 is provided can be a red sub-pixel SP2, an area in which a green color filter CF3 is provided can be a green sub-pixel SP3, and an area in which a color filter is not provided can be a white sub-pixel SP4. In the present disclosure, the blue sub-pixel SP1 can be expressed as a first sub-pixel provided to emit blue light, the red sub-pixel SP2 can be represented as a second sub-pixel provided to emit red light, the green sub-pixel SP3 can be expressed as a third sub-pixel provided to emit green light, and the white sub-pixel SP4 can be represented as a fourth sub-pixel provided to emit white light.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels can emit light with a predetermined brightness in accordance with the predetermined current.

As shown in FIG. 2, the display area DA includes a transmissive area TA and a non-light emission area NEA. The transmissive area TA is an area through which most of light incident from the outside passes, and the non-light emission area NEA is an area that does not transmit most of light incident from the outside. For example, the non-light emission area NEA can be an area other than the light emission area EA from which light is emitted. In one example, the non-light emission area NEA can be provided on the substrate 110 between the transmissive area TA and the plurality of sub-pixels SP, and between the plurality of sub-pixels SP.

In the non-light emission area NEA, a plurality of lines for driving each of the plurality of pixels P can be disposed. The plurality of lines, according to one example, can include a plurality of first signal lines SL1 and a plurality of second signal lines SL2.

The plurality of first signal lines SL1 can be extended in the first direction (X-axis direction). Each of the plurality of first signal lines SL1 can include at least one gate line.

Hereinafter, when the first signal line SL1 includes a plurality of lines, one first signal line SL1 can refer to a signal line group comprised of a plurality of lines. For example, when the first signal line SL1 includes two gate lines GL, one first signal line SL1 can refer to a signal line group comprised of two gate lines. For example, as shown in FIG. 2, the gate line GL can include a first gate line GL1 arranged on an upper side of the pixel P and a second gate line GL2 arranged on a lower side of the pixel P. The first gate line GL1 can be placed on an upper side of the transmissive area TA, and the second gate line GL2 can be placed on a lower side of the transmissive area TA. For example, the first gate line GL1 can be arranged spaced apart from the second gate line GL2 with the transmissive area TA and the plurality of subpixels SP interposed therebetween.

The plurality of second signal lines SL2 can extend in the second direction (Y-axis direction). The plurality of second signal lines SL2 can intersect with the plurality of first signal lines SL1. Each of the plurality of second signal lines SL2 can include a pixel power line EVDD, and a common power line EVSS disposed spaced apart from the pixel power line EVDD. In an embodiment, the plurality of second signal lines SL2 can further include a plurality of data lines DL, and a reference line RL. The plurality of data lines DL can include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

Hereinafter, when the second signal line SL2 includes a plurality of lines, one second signal line SL2 can refer to a signal line group comprised of a plurality of lines. For example, when the second signal line SL2 includes four data lines, a pixel power line, a common power line and a reference line, one second signal line SL2 can refer to a signal line group comprised of four data lines, a pixel power line, a common power line and a reference line.

At least one transmissive area TA can be disposed between the first signal lines SL1 adjacent to each other. In addition, at least one transmissive area TA can be disposed between the second signal lines SL2 adjacent to each other. For example, the transmissive area TA can be surrounded by two first signal lines SL1 and two second signal lines SL2. However, it is not limited thereto, and depending on the arrangement structure of the line, the first signal line SL1 can be arranged to cross the transmissive area TA (or between the first subpixel SP1 and the third subpixel SP3).

Referring back to FIG. 1, the non-display area NDA is an area on which an image is not displayed, and can be a peripheral circuit area, a signal supply area, an inactive area or a bezel area. The non-display area NDA can be configured to be in the vicinity of the display area DA. For example, the non-display area NDA can be disposed to surround the display area DA.

The transparent display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. The non-display area NDA can include a first non-display area NDA1, a second non-display area NDA2, a third non-display area NDA3, and a fourth non-display area NDA4. The pad portion PA according to one example can be disposed in the first non-display area NDA1.

The gate driver GD supplies gate signals to the gate lines in accordance with the gate control signal input from the timing controller 160. The gate driver GD can be formed on one side of the display area DA of the display panel or on the non-display area NDA outside both sides of the display area DA in a gate driver in panel (GIP) method as shown in FIG. 1. Alternatively, the gate driver GD can be manufactured as a driving chip, packaged in a flexible film and attached to the non-display area NDA outside one side or both sides of the display area DA of the display panel by a tape automated bonding (TAB) method.

The plurality of gate drivers GD can be separately disposed on a left side of the display area DA, for example, the second non-display area NDA2 and a right side of the display area DA, for example, the third non-display area NDA3. According to one example, the plurality of gate drivers GD can be connected to the plurality of pixels P and the plurality of first signal lines SL1 for supplying signals to the plurality of pixels P. The plurality of first signal lines SL1 can include at least one signal line for supplying a signal for driving the pixel P.

The plurality of second signal lines SL2 can be extended in the second direction (Y-axis direction). The plurality of second signal lines SL2 can cross the plurality of first signal lines SL1. The plurality of second signal lines can include a pixel power line VDD and at least one data line to supply a data voltage to the pixel P. Each of the plurality of second signal lines SL2 can be connected to at least one of a plurality of pads, a pixel power shorting bar VDDB or a common power shorting bar VSSB. The pixel power shorting bar VDDB and the common power shorting bar VSSB can be disposed in the fourth non-display area NDA4 that is disposed to face the pad area PA based on the display area DA.

The pixels are provided to overlap at least one of the first signal line SL1 or the second signal line SL2 and emit predetermined light to display an image. The light emission area EA can correspond to an area, which emits light, in the pixel P.

Each of the blue sub-pixel SP1 (or first sub-pixel SP1), the red sub-pixel SP2 (or second sub-pixel SP2), the green sub-pixel SP3 (or third sub-pixel SP3), and the white sub-pixel SP4 (or fourth sub-pixel SP4) can comprise at least one or more light emission areas. The at least one light emission area of each of the sub-pixels SP1, SP2, SP3, SP4 can have the same shape and size, but is not necessarily limited thereto.

Referring to FIGS. 2 and 3, in the transparent display apparatus 100 according to one embodiment of the present disclosure, the non-light emission area NEA can be provided between the transmissive area TA and the plurality of sub-pixels SP1, SP2, SP3 and SP4 and between the plurality of sub-pixels SP1, SP2, SP3 and SP4 on the substrate 110.

The non-light emission area NEA can refer to an area that is provided in the display area DA and does not emit light, and can be expressed as a dead zone because it does not emit light. The dead zone according to one example can be an area in which a black matrix and/or a bank is provided, but is not limited thereto, and can refer to an area in which light is not emitted.

The non-light emission area NEA can have the plurality of lines, for example, first signal lines SL1 and second signal lines SL2 can be disposed. The first signal lines SL1 according to an example can include the gate line GL disposed extending in the first direction (X-axis direction). The second signal lines SL2 according to an example can include the pixel power line EVDD, the common power line EVSS, the reference line RL, and the plurality of data lines DL, which are extending in the second direction (Y-axis direction).

The transparent display apparatus 100 according to one embodiment of the present disclosure can include a color pattern portion 120 partially overlapping a transmissive area TA.

The color pattern portion 120 is intended to minimize (or reduce) the yellowish color of a background and/or an object shown to the user through the transmissive area TA. Therefore, the color pattern portion 120 can be positioned to partially overlap the transmissive area TA. For example, the color pattern portion 120 can be arranged along an edge of the transmissive area TA. Accordingly, as shown in FIG. 2, the color pattern portion 120 according to one example can be arranged in a square frame (also referred to herein as a square ring) shape in the transmissive area TA. However, it is not limited thereto, and the color pattern portion 120 can be arranged in a different shape (e.g., a stripe shape) in the transmissive area TA if it can reduce the yellowish color of the background and/or the object.

The color pattern portion 120 can include or be provided with at least one of a blue pattern portion, a red pattern portion, and a green pattern portion. For example, if the background and/or the object shown to the user through the transmissive area TA has a yellowish color, the color pattern portion 120 can be provided with a blue pattern portion. Since the color pattern portion 120 is provided as a blue pattern portion, a yellowish color tone can be reduced, and as a result, the original color tone (or neutral color tone) of the background and/or the object can be shown to the user.

Therefore, the transparent display apparatus 100 according to one embodiment of the present disclosure can be provided with the color pattern portion 120 partially overlapping the transmissive area TA, so that the yellowish color (or other color) of the background and/or the object can be minimized, thereby providing the user with the original color (or neutral color) of the background and/or the object.

In the above, the yellowish color of the background and/or the object was used as an example for explanation, but if the background and/or the object has a different color, the color pattern portion 120 can be provided as the red pattern portion or the green pattern portion, or at least two or more of the blue pattern portion, the red pattern portion, and the green pattern portion can be provided in an overlapping manner. Hereinafter, the color pattern portion 120 is described as the blue pattern portion as an example.

In the transparent display apparatus 100 according to one embodiment of the present disclosure, the color pattern portion 120 can be formed together with a color filter CF. Accordingly, the transparent display apparatus 100 according to one embodiment of the present disclosure can form the color filter CF and the color pattern portion 120 together without an additional process, thereby reducing the yellowish color of the background and/or the object without increasing the manufacturing cost.

Meanwhile, in the transparent display apparatus 100 according to one embodiment of the present disclosure, the color pattern portion 120 can include an inner line INL arranged spaced apart from the plurality of subpixels SP. For example, the inner line INL can mean a line arranged in the transmissive area TA spaced apart from a black matrix BM (or gate line GL). The inner line INL can be provided in a straight shape. According to one example, the inner line INL can include two vertical lines spaced apart from the common power line EVSS in the first direction (X-axis direction), and two horizontal lines connected to the two vertical lines. Accordingly, the transparent display apparatus 100 according to one embodiment of the present disclosure can have an inner line INL formed in the straight line shape, so that the color pattern portion 120 can be formed in a square frame shape. Therefore, the transparent display apparatus 100 according to one embodiment of the present disclosure has a uniform shape of the transmissive area TA (or the outer side and inner side of the transmissive area TA), so that the diffraction phenomenon does not occur, thereby improving the clarity of the background and/or the object.

In the case of a general display apparatus, since a plurality of lines are arranged in a non-light emission area between a plurality of subpixels SP and a transmissive area TA, a shape of the transmissive area TA adjacent to the plurality of subpixels SP is not uniform. For example, in the case of a general display apparatus, the shape of a transmissive area TA adjacent to the plurality of subpixels SP can be convex due to a plurality of lines arranged in a non-light emission area. Therefore, in the case of general display apparatus, there is a problem of reduced clarity of the background and/or the objects due to diffraction phenomena caused by the non-uniform shape of the transmissive area TA.

In contrast, the transparent display apparatus 100 according to one embodiment of the present disclosure has the inner line INL of the color pattern portion 120 formed in a straight line, so that a diffraction phenomenon does not occur, thereby improving the clarity of the background and/or the object.

In addition, since the transparent display apparatus 100 according to aspects of the present disclosure does not cause the diffraction phenomenon due to the color pattern portion 120, the clarity (or visibility) of the image can be improved, and thus, compared to a display apparatus without a color pattern portion, the light emission efficiency can be improved to the same or higher with low power, so that the overall power consumption can be reduced.

As a result, the transparent display apparatus 100 according to aspects of the present disclosure can improve the clarity of the image and the background (and/or object) by including the color pattern portion 120 partially overlapping the transmissive area TA, and can also reduce or prevent the yellowish color tone of the background and/or the object.

Meanwhile, the transparent display apparatus 100 according to one embodiment of the present disclosure can include a cathode contact portion CCP connected to a common power line EVSS. The cathode contact portion CCP is electrically connected to an opposing electrode 117 (or a cathode electrode) and can transmit a common voltage applied to the common power line EVSS to the opposing electrode 117 (or the cathode electrode). As shown in FIG. 2, the cathode contact portion CCP according to one example can be placed in the transmissive area TA (or the transmissive area TA located inside the inner line INL of the color pattern portion 120).

Referring to FIG. 2, the plurality of sub-pixels SPs can include the first sub-pixel SP1 and the third sub-pixel SP3 spaced apart in the second direction (Y-axis direction), and the second sub-pixel SP2 and the fourth sub-pixel SP4 spaced apart in the first direction (X-axis direction) from each of the first sub-pixel SP1 and the third sub-pixel SP3. The transmissive area TA can be disposed adjacent to each of the second sub-pixel SP2 and the fourth sub-pixel SP4. However, it is not limited thereof, the arrangement structure of the plurality of sub-pixels SPs can be varied depending on the circuit design. For example, the first sub-pixel SP1, the second sub-pixel SP2, the third sub-pixel SP3, and the fourth sub-pixel SP4 can be disposed in a row in the second direction (Y-axis direction), and the transmissive area TA can be disposed adjacent to each of the first sub-pixel SP1, the second sub-pixel SP2, the third sub-pixel SP3, and the fourth sub-pixel SP4 in the first direction (X-axis direction). Hereinafter, each of the first to fourth sub-pixels SP1, SP2, SP3, SP4 will be described as an example in which the first to fourth sub-pixels SP1, SP2, SP3, SP4 are arranged in a square shape, as shown in FIG. 3.

Hereinafter, with reference to FIG. 3, the structure of each of the plurality of sub-pixels SPs will be described in detail.

Referring to FIG. 3, a transparent display apparatus 100 according to one embodiment of the present disclosure can include a buffer layer BL, a circuit element layer 111, a thin film transistor 112, an overcoat layer 113, a pixel electrode 114, a bank 115, an organic light emitting layer 116, an opposing electrode 117, a filling layer 118, a color filter CF, and a black matrix BM.

In more detail, each of the subpixels SP according to one embodiment can include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, an organic light emitting layer 116 on the pixel electrode 114 and the bank 115, an opposing electrode 117 on the organic light emitting layer 116, a filling layer 118 on the opposing electrode 117, and the color filter CF and the black matrix BM on the filling layer 118.

The thin film transistor 112 for driving the subpixel SP can be disposed on the circuit element layer 111. The circuit element layer 111 can be expressed as the term of an inorganic film layer. The buffer layer BL can be included in the circuit element layer 111 together with the gate insulating layer 111a, the interlayer insulating layer 111b and the passivation layer 111c. The pixel electrode 114, the organic light emitting layer 116 and the opposing electrode 117 can be included in the light emitting element layer E.

The buffer layer BL can be formed between the substrate 110 and the gate insulating layer 111a to protect the thin film transistor 112. The buffer layer BL can be disposed on the entire surface (or front surface) of the substrate 110. The pixel power line EVDD for pixel driving can be disposed between the buffer layer BL and the substrate 110. The pixel power line EVDD can be disposed below the bank 115 while being spaced apart from the thin film transistor 112. The reference line RL can also be disposed between the buffer layer BL and the substrate 110. The reference line RL can be disposed in the non-light emission area NEA that does not overlap with the light emission area EA. The buffer layer BL can serve to block diffusion of a material contained in the substrate 110 into a transistor layer during a high temperature process of a manufacturing process of the thin film transistor. Optionally, the buffer layer BL can be omitted in some cases.

The thin film transistor 112 (or a drive transistor) according to an example can include an active layer 112a, a gate electrode 112b, a source electrode 112c, and a drain electrode 112d.

The active layer 112a can include a channel area, a drain area and a source area, which are formed in a thin film transistor area of a circuit area of the subpixel SP. The drain area and the source area can be spaced apart from each other with the channel area interposed therebetween.

The active layer 112a can be formed of a semiconductor material based on any one of amorphous silicon, polycrystalline silicon, oxide and organic material.

The gate insulating layer 111a can be formed on the channel area of the active layer 112a. As an example, the gate insulating layer 111a can be formed in an island shape only on the channel area of the active layer 112a, or can be formed on an entire front surface of the substrate 110 or the buffer layer BL, which includes the active layer 112a.

The gate electrode 112b can be formed on the gate insulating layer 111a to overlap the channel area of the active layer 112a.

The interlayer insulating layer 111b can be formed on the gate electrode 112b and the drain area and the source area of the active layer 112a. As in FIG. 3, the interlayer insulating layer 111b can be formed in an entire light emission area, in which light is emitted to the subpixel SP. However, embodiments of the present disclosure are not limited thereto, the interlayer insulating layer 111b can be patterned between the drain electrode 112d and the gate electrode 112b and drain region of the active layer 112a and can be arranged in an island shape, and moreover, can be patterned between the source electrode 112c and the gate electrode 112b and source region of the active layer 112a and can be arranged in an island shape.

The source electrode 112c can be electrically connected to the source area of the active layer 112a through a source contact hole provided in the interlayer insulating layer 111b overlapped with the source area of the active layer 112a. The drain electrode 112d can be electrically connected to the drain area of the active layer 112a through a drain contact hole provided in the interlayer insulating layer 111b overlapped with the drain area of the active layer 112a.

The drain electrode 112d and the source electrode 112c can be made of the same metal material. For example, each of the drain electrode 112d and the source electrode 112c can be made of a single metal layer, a single layer of an alloy or a multi-layer of two or more layers, which is the same as or different from that of the gate electrode.

In addition, the circuit area can further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor can be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 can further include a light shielding layer LS provided below the active layer 112a of at least one of the thin film transistor 112, the first switching thin film transistor or the second switching thin film transistor. The light shielding layer can be disposed between the substrate 110 and the active layer 112a to shield light incident on the active layer 112a through the substrate 110, thereby minimizing a change in the threshold voltage of the transistor due to external light. Further, since the light shielding layer is provided between the substrate 110 and the active layer 112a, the thin film transistor can be prevented from being seen by a user.

The passivation layer 111c can be provided on the substrate 110 to cover the pixel area. The passivation layer 111c covers a drain electrode 112d, a source electrode 112c and a gate electrode 112b of the thin film transistor 112, and the buffer layer BL. The passivation layer 111c can be formed over the circuit area and the light emission area. The passivation layer 111c can be omitted.

The overcoat layer 113 can be provided on the substrate 110 to cover the passivation layer 111c. When the passivation layer 111c is omitted, the overcoat layer 113 can be provided on the substrate 110 to cover the circuit area (or the thin film transistor 112). The overcoat layer 113 can be formed in the circuit area CA in which the thin film transistor 112 is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

On the other hand, the upper surface of the overcoat layer 113 can be provided flatly. Accordingly, the pixel electrodes 114 on the overcoat layer 113 can also be provided flatly, and the organic light emitting layer 116 and the opposing electrode 117 formed thereon can also be provided flatly. Since the pixel electrode 114, the organic light emitting layer 116, the opposing electrode 117, for example, the light emitting element layer E is provided to be flat in the light emission area EA, a thickness of each of the pixel electrode 114, the organic light emitting layer 116 and the opposing electrode 117 in the light emission area EA can be uniformly formed. Therefore, the organic light emitting layer 116 can be uniformly emitted without deviation in the light emission area EA.

The pixel electrodes 114 according to one example can be formed on the overcoat layer 113. The pixel electrode 114 can be connected to a drain electrode or a source electrode of the thin film transistor 112 through a contact hole passing through the overcoat layer 113 and the passivation layer 111c. The one edge portion of the pixel electrode 114 can be covered by the bank 115. The pixel electrode 114 can be made of at least one of a transparent metal material or a semi-transmissive metal material.

Since the transparent display apparatus 100 according to one embodiment of the present disclosure is top-emission type, the pixel electrodes 114 can be made of a highly reflective metallic material or a stacked structure of a highly reflective metallic material and a transparent metallic material. For example, the pixel electrode 114 can be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy can be an alloy such as silver (Ag), palladium (Pd), and copper (Cu).

Meanwhile, the material constituting the pixel electrode 114 can include MoTi. The pixel electrode 114 can be a first electrode or an anode electrode.

The bank 115 can be an area, which does not emit light, and disposed on one side of the light emission area EA of each of the plurality of sub-pixels SP. For example, the bank 115 can be disposed in the non-light emission area NEA. The bank 115 can be formed to cover a portion where the edge of the pixel electrode 114. Accordingly, the bank 115 can prevent the pixel electrode 114 and the opposing electrode 117 in the edge of the pixel electrode 114. The exposed portion of the pixel electrode 114 that is not covered by the bank 115 can be included in the light emitting portion (or light emission area EA).

After the bank 115 is formed, an organic light emitting layer 116 can be formed to cover the pixel electrodes 114 and the bank 115. Thus, the bank 115 can be partially provided between the pixel electrodes 114 and the organic light emitting layer 116. The bank 115 can be expressed in terms of a pixel-defining membrane. The bank 115 according to one example can comprise organic material and/or inorganic material.

Referring again back to FIG. 3, the organic light emitting layer 116 can be formed on the pixel electrodes 114 and the bank 115. According to one example, the organic light emitting layer 116 can be disposed in the light emission area EA and the non-light emission area NEA. The organic light emitting layer 116 can be provided between the pixel electrode 114 and the opposing electrode 117. Thus, when a voltage is applied to each of the pixel electrode 114 and the opposing electrode 117, an electric field is formed between the pixel electrode 114 and the opposing electrode 117. Therefore, the organic light emitting layer 116 can emit light. The organic light emitting layer 116 can be formed of a plurality of subpixels SP and a common layer provided on the bank 115.

The organic light emitting layer 116 according to an embodiment can be provided to emit white light. The organic light emitting layer 116 can include a plurality of stacks which emit lights of different colors. For example, the organic light emitting layer 116 can include a first stack, a second stack, and a charge generating layer (CGL) provided between the first stack and the second stack. The light emitting layer can be provided to emit the white light, and thus, each of the plurality of subpixels SP can include a color filter CF suitable for a corresponding color.

The first stack can be provided on the pixel electrode 114 and can be implemented in a structure where a hole injection layer (HIL), a hole transport layer (HTL), an emission layer (EML(B)), and an electron transport layer (ETL) are sequentially stacked.

The charge generating layer can supply an electric charge to the first stack and the second stack. The charge generating layer can include an N-type charge generating layer for supplying an electron to the first stack and a P-type charge generating layer for supplying a hole to the second stack. The N-type charge generating layer can include a metal material as a dopant.

The second stack can be provided on the first stack and can be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack can be arranged all over the plurality of subpixels SP. The organic light emitting layer 116, according to another example, can be provided in a three-stacked structure or a four-stacked structure, depending on the number of stacks stacked.

The opposing electrode 117 can be formed on the organic light emitting layer 116. The opposing electrode 117 can be disposed in the light emission area EA and the non-light emission area NEA. The opposing electrode 117 according to one example can include a metal material. The opposing electrode 117 can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

Since the transparent display apparatus 100 according to one embodiment of the present disclosure is top-emission type, the opposing electrodes 117 can be formed of a transparent conductive material TCO such as ITO, IZO, that is capable of transmitting light or a semi-transmissive conductive material TMCM such as magnesium (Mg), silver (Ag), or an alloy of magnesium (Mg) and silver (Ag). Such opposing electrodes 117 can be referred in terms of second electrodes, cathode electrodes.

The filling layer 118 is formed on the opposing electrodes 117. The filling layer 118 according to one example can be provided with an adhesive material that bonds the substrate 110 and the opposing substrate 200. The filling layer 118 serves to prevent oxygen or moisture from penetrating into the organic light emitting layer 116 and the opposing electrodes 117. To this end, the filling layer 118 can be configured to include a getter capable of absorbing oxygen or moisture.

On the other hand, as shown in FIG. 3, the filling layer 118 can be disposed not only in the light emission area EA but also in the non-light emission area NEA. The filling layer 118 can be disposed between the opposing electrodes 117 and the opposing substrate 200.

A color filter CF and a black matrix BM can be disposed between the filling layer 118 and the opposing substrate 200. the color filter CF according to one example can be arranged to overlap the light emission area EA. Since the color filter CF converts white light emitted from the light-emitting element layer E into light of different colors, it can be provided with a width larger than the light emission area EA. Therefore, as shown in FIG. 4, the color filter CF is provided with a width larger than the light emission area EA and can partially overlap not only the light emission area EA but also the non-light emission area NEA.

Meanwhile, the white light emitting portion SP4 can not (or may not) be provided with a color filter since the organic light emitting layer 116 emits white light. On the other hand, the blue sub-pixel SP1 can be provided with the first color filter (or blue color filter CF1) between the filling layer 118 and the opposing substrate 200. The red sub-pixel SP2 can be provided with the second color filter CF2 (or red color filter CF2) between the filling layer 118 and the opposing substrate 200. The green sub-pixel SP3 can be provided with the third color filter CF3 (or green color filter CF3) between the filling layer 118 and the opposing substrate 200. As shown in FIG. 3, the color filter CF can be configured to partially cover the black matrix BM.

On the other hand, the black matrix BM can be provided between the plurality of sub-pixels SP1, SP2, SP3, SP4 to prevent color mixing and/or light leakage. The black matrix BM can comprise a black colored material and can be disposed overlapping the bank 115. The area provided with the black matrix BM and/or the bank 115 can be a dead zone or the non-light emission area. The black matrix BM according to an example can be formed on an opposing substrate 200 to overlap at least a portion of the bank 115, thereby reducing the cell gap between the organic light emitting layer 116 and the opposing substrate 200 to prevent mixing of sub-pixels.

Referring again to FIG. 2, in the transparent display apparatus 100 according to one embodiment of the present disclosure, the black matrix BM can not be disposed between the fourth sub-pixel SP4, which is a white sub-pixel, and the transmissive area TA. This is because the fourth sub-pixel SP4 is configured to emit white light, and therefore, even if the black matrix BM is not disposed between the fourth sub-pixel SP4 and the transmissive area TA, color mixing can not (or may not) occur. Therefore, the transparent display apparatus 100 according to one embodiment of the present disclosure can have a structural feature in which the black matrix BM is not disposed between the fourth sub-pixel SP4 and the transmissive area TA.

The transparent display apparatus 100 according to one embodiment of the present disclosure can include a plurality of black matrices BM arranged between at least some subpixels of the plurality of subpixels SP and the transmissive area TA. For example, the plurality of black matrices BM can include a black matrix BM on a left side of the transmissive area TA and a black matrix BM on a right side of the transmissive area TA based on FIG. 2. Each of the plurality of black matrices BM can be arranged to overlap with the pixel power line EVDD, as shown in FIG. 2. Here, the color pattern portion 120 can be arranged to partially overlap each of the plurality of black matrices BM or adjacent to each of the plurality of black matrices BM.

For example, as shown in FIG. 4, the color pattern portion 120 can be partially overlapped with a black matrix BM partially covered by the second color filter CF2. If the color pattern portion 120 is positioned apart from the black matrix BM, a gap is formed between the black matrix BM and the color pattern portion 120, and light leakage can occur through this gap. Accordingly, in the transparent display apparatus 100 according to one embodiment of the present disclosure, the color pattern portion 120 is arranged to partially overlap each of the plurality of black matrices BM or to be adjacent to each of the plurality of black matrices BM, thereby preventing a gap from being formed between the black matrix BM and the color pattern portion 120, and thus light leakage can be prevented.

Referring again to FIG. 2, the transparent display apparatus 100 according to one embodiment of the present disclosure can include a plurality of gate lines GL arranged lengthwise in the first direction (X-axis direction) between the plurality of pixels P. For example, the plurality of gate lines GL can include a first gate line GL1 arranged above the pixel P and a second gate line GL2 arranged below the pixel P based on the pixel P illustrated in FIG. 2. The first gate line GL1 can be arranged long in the first direction (X-axis direction) parallel to the second gate line GL2 with the plurality of sub-pixels SP (e.g., the first sub-pixel SP1 and the third sub-pixel SP3) interposed therebetween. Here, each of the plurality of black matrices BM can be arranged lengthwise in the second direction (Y-axis direction) intersecting the first direction (X-axis direction). For example, the black matrix BM on a left side of the transmissive area TA can be arranged lengthwise in the second direction (Y-axis direction) parallel to the black matrix (BM) on a right side of the transmissive area TA with the transmissive area TA in between. Therefore, as illustrated in FIG. 2, the transparent display apparatus 100 according to one embodiment of the present disclosure can have a structural feature in which the color pattern portion 120 is partially disposed between the plurality of gate lines GL and between the plurality of black matrices BM. In addition, as illustrated in FIG. 2, a transparent display apparatus 100 according to one embodiment of the present disclosure can have a structural feature in which a color pattern portion 120 partially covers each of the plurality of gate lines GL (e.g., the first gate line GL1 and the second gate line GL2).

Meanwhile, in the transparent display apparatus 100 according to one embodiment of the present disclosure, the color pattern portion 120 can include a plurality of first color pattern portions 121 and a plurality of second color pattern portions 122.

According to one example, the plurality of first color pattern portions 121 can be arranged in parallel along respective ones of the plurality of black matrices BM. For example, as shown in FIG. 2, the plurality of first color pattern portions 121 can include a first vertical color pattern portion 121a arranged lengthwise in the second direction (Y-axis direction) along the black matrix BM on the left side of the transmissive area TA, and a second vertical color pattern portion 121b arranged lengthwise in the second direction (Y-axis direction) along the black matrix BM on the right side of the transmissive area TA.

According to one example, the plurality of second color pattern portions 122 can be connected to respective ones of the plurality of first color pattern portions 121 and can be arranged in parallel along respective ones of the plurality of gate lines GL. For example, as shown in FIG. 2, the plurality of second color pattern portions 122 can include a first horizontal color pattern portion 122a arranged long in the first direction (X-axis direction) along the first gate line GL1 on the upper side of the transmissive area TA, and a second horizontal color pattern portion 122b arranged long in the first direction (X-axis direction) along the second gate line GL2 on the lower side of the transmissive area TA. The transparent display apparatus 100 according to one embodiment of the present disclosure can be provided with a closed loop structure in which the first vertical color pattern portion 121a, the second vertical color pattern portion 121b, the first horizontal color pattern portion 122a, and the second horizontal color pattern portion 122b are connected to each other.

Hereinafter, with reference to FIGS. 4 to 6, the color pattern portion 120 included in the transparent display apparatus 100 according to one embodiment of the present disclosure will be described in more detail.

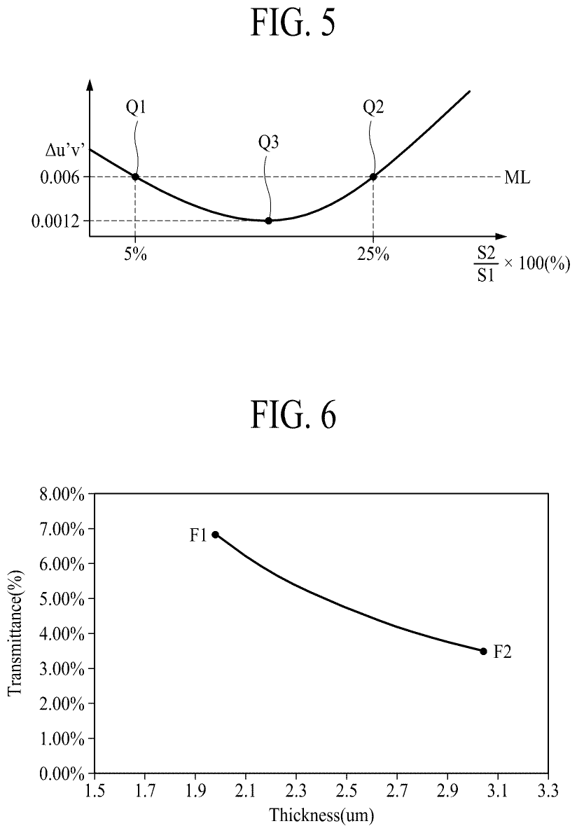

FIG. 5 is a schematic graph showing color sensation according to the ratio of a color pattern portion overlapping a transmissive area of a transparent display apparatus according to one embodiment of the present disclosure, and FIG. 6 is a schematic graph showing a transmittance of a transmissive area according to the thickness of a color pattern portion overlapping a transmissive area of a transparent display apparatus according to one embodiment of the present disclosure.

Referring to FIG. 4, the transparent display apparatus 100 according to one embodiment of the present disclosure can be manufactured by bonding the substrate 110 and the opposing substrate 200. For example, a transparent display apparatus 100 according to one embodiment of the present disclosure can be manufactured by bonding the substrate 110 on which the light-emitting element layer E is formed, and the opposing substrate 200 on which the color filter CF and the black matrix BM are formed. Therefore, the color filter CF and the black matrix BM can be first formed on the opposing substrate 200 before the opposing substrate 200 and the substrate 110 are bonded. Accordingly, the transparent display apparatus 100 according to one embodiment of the present disclosure can have a structural feature in which a width CFW of the color filter CF (or the second color filter CF2) increases in an upward direction UD toward the light-emitting element layer E from the substrate 110.

In addition, the transparent display apparatus 100 according to one embodiment of the present disclosure can also have a structural feature in which a width BMW of the black matrix BM increases in the upward direction UD toward the light-emitting element layer E from the substrate 110.

As a result, the transparent display apparatus 100 according to one embodiment of the present disclosure is provided with a structure in which the substrate 110 and the opposing substrate 200 are bonded, so that each of the color filter CF and the black matrix BM can be provided in a reverse taper shape in which the width increases as it goes in the upward direction UD. Meanwhile, since the color pattern portion 120 is also formed on the opposing substrate 200 and then bonded to the substrate 110, the color pattern portion 120 can also be provided in a reverse taper shape in which the width (of at least a portion of the color pattern portion) increases as it goes in the upward direction UD.

Referring again to FIG. 4, in the transparent display apparatus 100 according to one embodiment of the present disclosure, the color pattern portion 120 can be arranged to partially overlap the transmissive area TA in order to minimize (or reduce) a yellowish color of a background and/or an object. Accordingly, the color pattern portion 120 can occupy a predetermined area in the transmissive area TA.

In the transparent display apparatus 100 according to one embodiment of the present disclosure, the area of the color pattern portion 120 can be provided at a ratio of 5% to 25% of the area of the transmissive area TA. For example, the proportion of the color pattern portion 120 in the transmissive area TA can be 5% to 25%. If the proportion of the color pattern portion 120 (e.g., the blue pattern portion) in the transmissive area TA is less than 5%, a yellowish color can be displayed to the user because the proportion of the blue pattern portion in the transmissive area TA is low. And, if the proportion of the color pattern portion 120 (e.g., the blue pattern portion) in the transmissive area TA exceeds 25%, a bluish color can be displayed to the user because the proportion of the blue pattern portion in the transmissive area TA is high. Accordingly, in the transparent display apparatus 100 according to one embodiment of the present disclosure, the area of the color pattern portion 120 is provided at a ratio of 5% to 25% of the area of the transmissive area (TA), so that the yellowish color (or other color) of the background and/or the object can be minimized.

Referring to FIG. 5, the color sensation according to the ratio of the color pattern portion 120 overlapping the transmissive area TA is explained. The horizontal axis represents the ratio of an area S1 of the transmissive area TA to an area S2 of the color pattern portion 120, and the vertical axis represents the color sensation or color sensation value (Δu′v′). ML can refer to a baseline where the user does not perceive a difference in color between the background and/or the objects shown through the transmissive area TA. For example, if the color sensation value exceeds 0.006, the user can feel a difference in color sensation, and if the color sensation value is 0.006 or less, the user may not feel a difference in color sensation. The graph has a pattern in which the color sensation decreases and then increases as it goes to the right, with the horizontal axis pointing toward Q1, Q3, and Q2. This can mean that as the area occupied by the color pattern portion 120 in the transmissive area TA increases, the color sensation difference decreases significantly and then increases again. Accordingly, if the area occupied by the color pattern portion 120 in the transmissive area TA is less than or exceeds a specific area, the user can feel a significant difference in the color sensation of the background and/or the object.

For example, when the ratio of the area S1 of the transmissive area TA to the area S2 of the color pattern portion 120 in Q1 is 5%, the color sensation value is 0.006, when the ratio of the area S1 of the transmissive area TA to the area S2 of the color pattern portion 120 in Q2 is 25%, the color sensation value is 0.006, and when the ratio of the area S1 of the transmissive area TA to the area S2 of the color pattern portion 120 in Q3 is approximately 15%, the color sensation value can have a minimum value of 0.0012. Therefore, in this case, since the color sensation value is less than 0.006, the user cannot perceive the difference in color sensation between the background and/or the objects.

In contrast, at ratios lower than Q1 (or 5%), the color sensation exceeds 0.006.Accordingly, in this case, since the area occupied by the color pattern portion 120 in the transmissive area TA is small, the user can feel a yellowish color tone of the background and/or the object. In addition, at a ratio higher than Q2 (or 25%), the color sensation exceeds 0.006. Therefore, in this case, since the area occupied by the color pattern portion 120 in the transmissive area TA is large, the user can perceive a bluish color tone of the background and/or the objects.

Therefore, the transparent display apparatus 100 according to one embodiment of the present disclosure can have the area of the color pattern portion 120 provided at a ratio of 5% to 25% of the area of the transmissive area TA, so that the yellowish color of the background and/or the object shown through the transmissive area TA can be provided at 0.006 or less. Therefore, the transparent display apparatus 100 according to one embodiment of the present disclosure can allow the user to feel the natural color (or the neutral color) of the background and/or the object.

Meanwhile, referring to FIG. 4, the transparent display apparatus 100 according to one embodiment of the present disclosure can have a thickness T1 of the color pattern portion 120 thinner than a thickness T2 of the color filter CF. If the thickness of the color pattern portion 120 is equal to or thicker than the thickness of the color filter CF, the color pattern portion 120 greatly reduces the transmittance of the transmissive area TA. Accordingly, in the transparent display apparatus 100 according to one embodiment of the present disclosure, the thickness T1 of the color pattern portion 120 is provided thinner than the thickness T2 of the color filter CF, so that even if the color pattern portion 120 is placed in the transmissive area TA, the loss of transmittance can be minimized while reducing the yellowish color tone of the background and/or the object and converting it into a neutral color sensation.

In addition, the transparent display apparatus 100 according to one embodiment of the present disclosure is provided with the thickness T1 of the color pattern portion 120 thinner than the thickness T2 of the color filter CF, so that even when the color pattern portion 120 is arranged in a square frame shape along the edge of the transmissive area TA, as shown in FIG. 2, the loss of transmittance can be minimized while the yellowish color of the background and/or the object can be minimized. For example, the thickness T1 of the color pattern portion 120 can be less than half the thickness T2 of the color filter CF. According to an example, the color pattern portion 120 can be formed to have a thinner thickness than the color filter CF by controlling the exposure amount using a half-tone mask.

In the transparent display apparatus 100 according to one embodiment of the present disclosure, the thickness of the color pattern portion 120 can be inversely proportional to the transmittance of the transmissive area TA. In other words, the transmittance of the transmissive area TA may be inversely proportional to the thickness of the color pattern portion 120. Referring to FIG. 6, the transmittance of the transmissive area according to the thickness of the color pattern portion overlapping on the transmissive area is explained. The horizontal axis represents the thickness of the color pattern portion 120, and the vertical axis represents the transmittance of the transmissive area TA. The graph has a downward-sloping pattern as the thickness of the color pattern portion 120 increases. This can mean that as the thickness of the color pattern portion 120 increases, the transmittance of the transmissive area TA decreases.

For example, when the thickness of the color pattern portion 120 in F1 is approximately 1.95 μm, the transmittance of the transmissive area TA can be approximately 6.8%. In contrast, when the thickness of the color pattern portion 120 in F2 is approximately 3.05 μm, the transmittance of the transmissive area TA can be 3.5%. Therefore, it can be seen that the thickness of the color pattern portion 120 and the transmittance of the transmissive area TA have an inversely proportional relationship with respect to each other. Therefore, in the transparent display apparatus 100 according to one embodiment of the present disclosure, the thickness T1 of the color pattern portion 120 is provided to be thinner than the thickness T2 of the color filter CF, so that even if the color pattern portion 120 is partially arranged in the transmissive area TA, the loss of transmittance can be minimized while the reduction in yellowish color tone of the background and/or the object can be maximized.

Meanwhile, in the transparent display apparatus 100 according to one embodiment of the present disclosure, as the thickness of the color pattern portion 120 becomes thinner, the area occupied by the color pattern portion 120 in the transmissive area TA can increase, so that various designs of the color pattern portion 120 for the transmissive area TA can be possible. Accordingly, the transparent display apparatus 100 according to one embodiment of the present disclosure can be equipped to satisfy the transmittance and clarity required by a user through various designs of the color pattern portion 120 for the transmissive area TA.

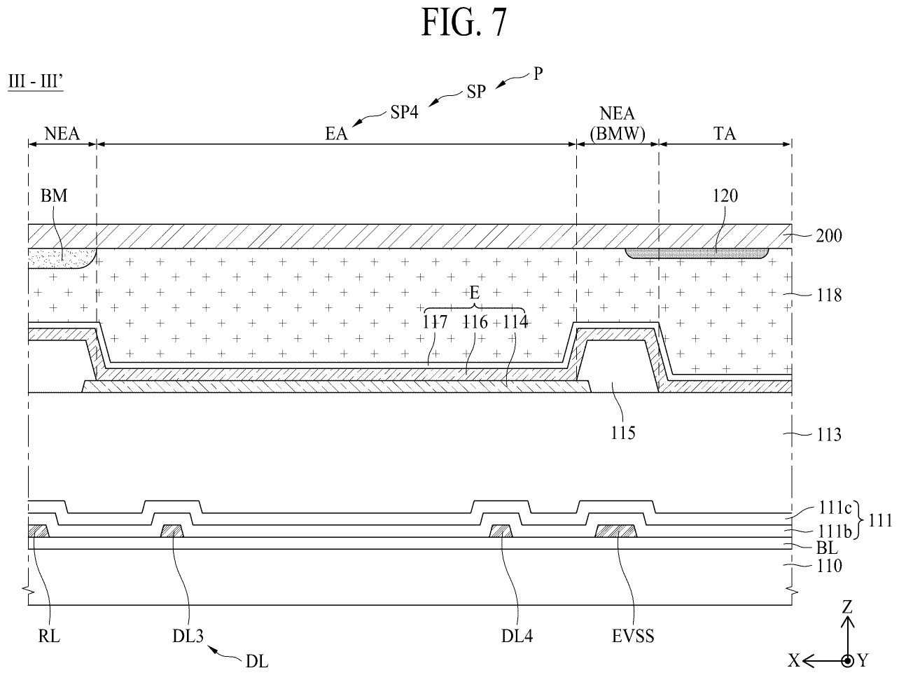

FIG. 7 is a schematic cross-sectional view of the line III-III′ shown in FIG. 2.

Referring to FIG. 7, in the transparent display apparatus 100 according to one embodiment of the present disclosure, the black matrix BM may not be placed between the fourth subpixel SP4, which is a white subpixel, and the transmissive area TA. Accordingly, the transparent display apparatus 100 according to one embodiment of the present t disclosure can have a structural feature in which the color pattern portion 120 partially contacts the opposing substrate 200 between the white subpixel SP4 and the transmissive area TA (or the non-light emission area NEA between the white subpixel SP4 and the transmissive area TA).

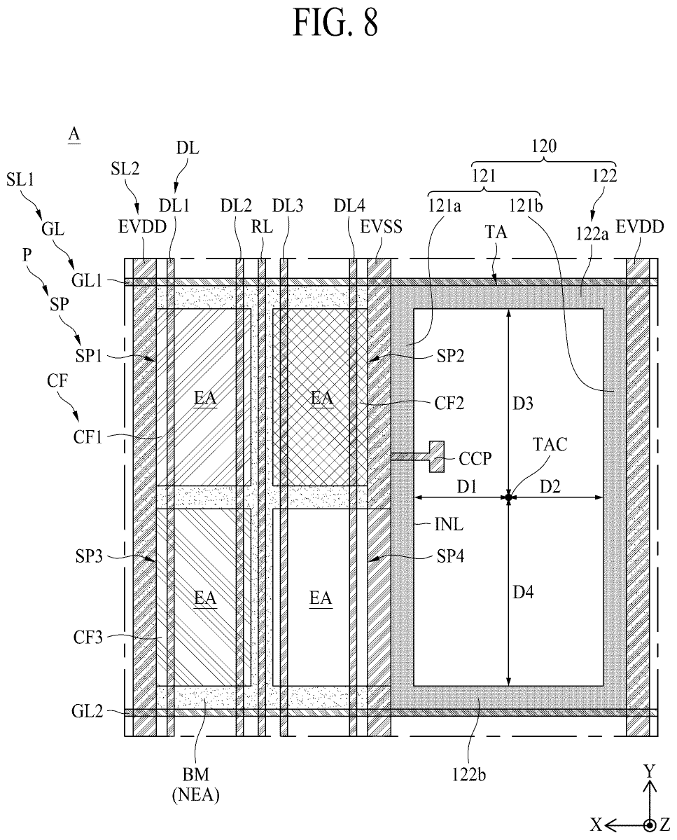

FIG. 8 is a schematic plan view showing the distance between a center of a transmissive area and a color pattern portion of a transparent display apparatus according to one embodiment of the present disclosure.

Referring to FIG. 8, the transparent display apparatus 100 according to one embodiment of the present disclosure can have the plurality of first color pattern portions 121 arranged spaced apart from a center TAC of the transmissive area TA, and the plurality of second color pattern portions 122 arranged spaced apart from the center TAC of the transmissive area TA. Here, the center TAC of the transmissive area TA can be the intersection of a virtual first line passing through the center between the plurality of black matrices BM and a virtual second line passing through the center between the plurality of gate lines GL. For example, an intersection point of a vertical line passing through the center between the black matrix BM on the left side of the transmissive area TA and the black matrix BM on the right side of the transmissive area TA, and a horizontal line passing through the center between the first gate line GL1 and the second gate line GL2 can be the center TAC of the transmissive area TA.

Therefore, the first vertical color pattern portion 121a can be arranged at a first distance D1 from the center TAC of the transmissive area TA, and the second vertical color pattern portion 121b can be arranged at a second distance D2 from the center TAC of the transmissive area TA. Further, the first horizontal color pattern portion 122a can be arranged at a third distance D3 from the center TAC of the transmissive area TA, and the second horizontal color pattern portion 122b can be arranged at a fourth distance D4 from the center TAC of the transmissive area TA.

If the plurality of first color pattern portions 121 are arranged up to the center TAC of the transmissive area TA and the plurality of second color pattern portions 122 are arranged up to the center TAC of the transmissive area TA, the color pattern portions 120 overlap the entire transmissive area TA, so not only is the transmittance of the transmissive area TA significantly lowered, but also a yellowish color tone can be converted into a bluish color tone.

Therefore, in the transparent display apparatus 100 according to one embodiment of the present disclosure, the plurality of first color pattern portions 121 are arranged spaced apart from the center TAC of the transmissive area TA, and the plurality of second color pattern portions 122 are arranged spaced apart from the center TAC of the transmissive area TA, so that, as shown in FIG. 8, the color pattern portion 120 can be provided in a square frame shape in the transmissive area TA, thereby minimizing a decrease in the transmittance of the transmissive area TA and reducing a yellowish color sensation of the background and/or the object.

Meanwhile, in the transparent display apparatus 100 according to one embodiment of the present disclosure, the first distance D1 and the second distance D2 can be the same or similar. If the difference between the first distance D1 and the second distance D2 is large, one of the plurality of first color pattern portions 121 is not placed in the transmissive area TA but in the non-light emission area NEA, so the yellowish color sensation of the background and/or the object is minimally reduced.

Similarly, the third distance D3 and the fourth distance D4 can be the same or similar. If the difference between the third distance D3 and the fourth distance D4 is large, one of the plurality of second color pattern portions 122 is placed in the transmissive area TA of another pixel P, so that the yellowish color sensation degradation of the background and/or the object is minimal with respect to one pixel P.

Therefore, in the transparent display apparatus 100 according to one embodiment of the present disclosure, the first distance D1 and the second distance D2 are provided to be the same or similar, and the third distance D3 and the fourth distance D4 are provided to be the same or similar, so that the color pattern portion 120 can maintain a constant area while being provided in a square frame shape in the transmissive area TA. Therefore, the transparent display apparatus 100 according to one embodiment of the present disclosure can convert the yellowish color tone of the background and/or object into a neutral color sensation, and can also improve the clarity of the background and/or the object.

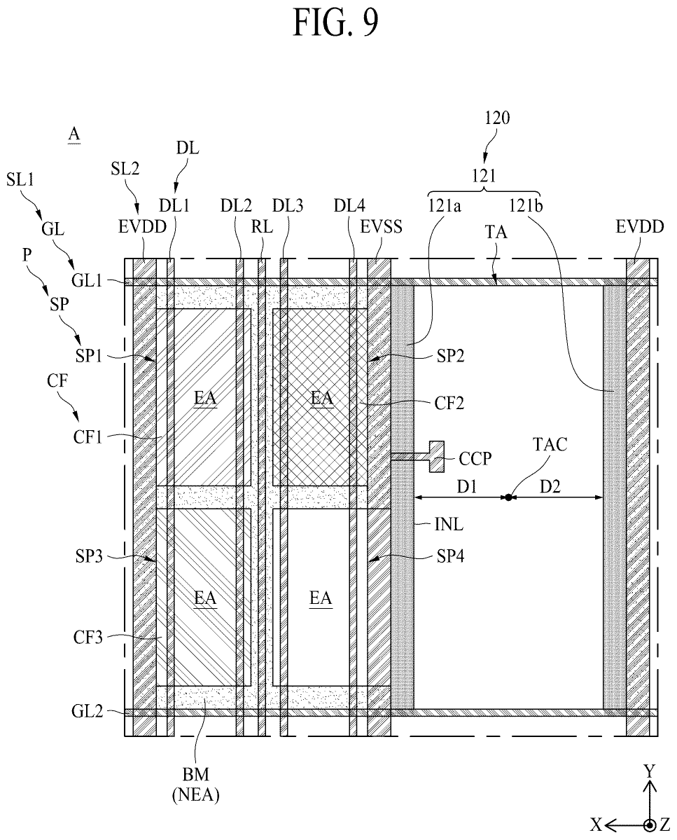

FIG. 9 is a plan view showing another example of a color pattern portion of a transparent display apparatus according to one embodiment of the present disclosure.

Referring to FIG. 9, in the transparent display apparatus 100 according to one embodiment of the present disclosure, according to another example, the color pattern portion 120 can be arranged in a stripe shape in the transmissive area TA. For example, the color pattern portion 120 can include the plurality of first color pattern portions 121 arranged in parallel along respective ones of the plurality of black matrices BM. The plurality of first color pattern portions 121 can include a first vertical color pattern portion 121a arranged lengthwise in the second direction (Y-axis direction) along the black matrix BM on the left side of the transmissive area TA, and a second vertical color pattern portion 121b arranged lengthwise in the second direction (Y-axis direction) along the black matrix BM on the right side of the transmissive area TA.

The plurality of first color pattern portions 121 (or the first vertical color pattern portion 121a and the second vertical color pattern portion 121b) can be arranged spaced apart from each other and from the center TAC of the transmissive area TA in the first direction (X-axis direction).

If the first vertical color pattern portion 121a is arranged up to the center TAC of the transmissive area TA and the second vertical color pattern portion 121b is arranged up to the center TAC of the transmissive area TA, the color pattern portion 120 overlaps the entire transmissive area TA, so not only is the transmittance of the transmissive area TA significantly lowered, but also a yellowish color tone can be converted into a bluish color tone.

Therefore, in the case of the transparent display apparatus 100 according to FIG. 9, the plurality of first color pattern portions 121 (or the first vertical color pattern portion 121a and the second vertical color pattern portion 121b) are arranged spaced apart from the center TAC of the transmissive area TA, so that the color pattern portion 120 can be provided in a stripe shape in the transmissive area TA, and as a result, the reduction in the transmittance of the transmissive area TA can be minimized while reducing the yellowish color of the background and/or the object.

Meanwhile, in the case of the transparent display apparatus 100 according to FIG. 9, the gate line GL on each of the upper and lower sides of the transmissive area TA is arranged in a long straight shape in the first direction (X-axis direction), so that each of an upper side and a lower side of the transmissive area TA can have a uniform shape. Accordingly, in the case of the transparent display apparatus 100 according to FIG. 9, even if the color pattern portion 120 is arranged in a stripe shape, the yellowish color of the background and/or the object can be converted to a neutral color without deteriorating the clarity of the background and/or the object.

In addition, since the transparent display apparatus 100 according to FIG. 9 has the color pattern portion 120 provided in a stripe shape in the transmissive area TA, the yield can be improved because the defect rate due to misalignment can be reduced compared to the case where the color pattern portion 120 is provided in a square frame shape. For example, since the transparent display apparatus 100 according to FIG. 9 has the color pattern portion 120 provided in the stripe shape in the transmissive area TA, only the alignment in the first direction (X-axis direction) needs to be adjusted, and thus, the defect rate due to misalignment can be reduced compared to a case where the alignment is adjusted in the first direction (X-axis direction) and the second direction (Y-axis direction).

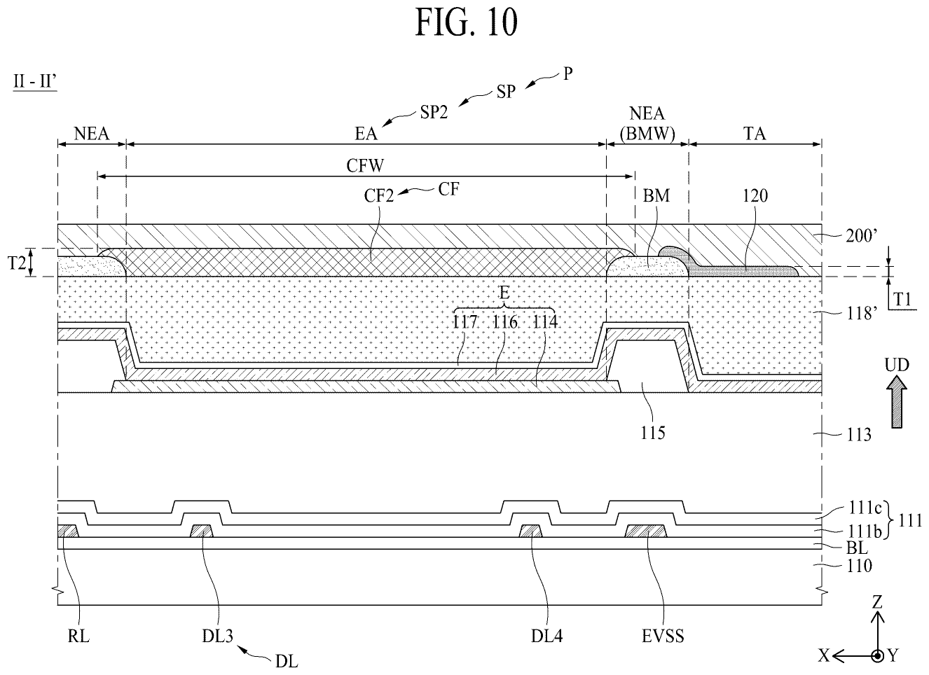

FIG. 10 is a cross-sectional view showing a transparent display apparatus according to another embodiment of the present disclosure.

Referring to FIG. 10, the transparent display apparatus 100 according to another embodiment of the present disclosure is the same as the transparent display apparatus according to FIG. 1 described above, except that the configuration above the light emitting element layer E is changed. Therefore, the same drawing symbols have been assigned to the same configuration, and the different configurations will be described hereinafter.

In the case of the transparent display apparatus according to the above-described FIG. 1, the substrate 110 and the opposing substrate 200 can be bonded and manufactured. For example, the transparent display apparatus according to FIG. 1 can be manufactured by bonding a substrate 110 on which the light-emitting element layer E is formed, and the opposing substrate 200 on which the color filter CF and the black matrix BM are formed. Accordingly, the transparent display apparatus 100 according to FIG. 1 can have a structural feature in which the width CFW of the color filter CF (or the second color filter CF2) increases from the substrate 110 toward the light-emitting element layer E in the upward direction UD, and the width BMW of the black matrix BM increases from the substrate 110 toward the light-emitting element layer E in the upward direction UD.

In contrast, in the case of the transparent display apparatus according to FIG. 10, an encapsulation layer 118′, a black matrix BM, a color filter CF, a color pattern portion 120, and an encapsulation film 200′ can be sequentially formed on a light-emitting element layer E. For example, the transparent display apparatus 100 according to FIG. 10 can be provided with a COE (Color on Encap) structure rather than a bonded structure. Therefore, as shown in FIG. 10, the encapsulation layer 118′ can be placed on the light-emitting element layer E, the black matrix BM can be placed on the encapsulation layer 118′, and the color filter CF can be placed partially overlapping or adjacent to the black matrix BM. Accordingly, in the case of the transparent display apparatus 100 according to another embodiment of the present disclosure, the width CFW of the color filter CF can have a structural feature in which it decreases in the upward direction UD toward the light-emitting element layer E from the substrate 110.

In addition, the transparent display apparatus 100 according to another embodiment of the present disclosure can also have a structural feature in which the width BMW of the black matrix BM decreases in the upward direction UD toward the light-emitting element layer E from the substrate 110.

As a result, the transparent display apparatus 100 according to another embodiment of the present disclosure can be provided with each of the color filter CF and the black matrix BM in a tapered shape in which the width decreases as it goes in the upward direction UD. Meanwhile, since the color pattern portion 120 is also formed on the encapsulation layer 118′ together with the color filter CF, as shown in FIG. 10, the color pattern portion 120 can also be provided in a tapered shape with the width of at least a portion of the color pattern portion 120 decreasing toward the upper direction UD.

Meanwhile, since the transparent display apparatus 100 according to another embodiment of the present disclosure does not have a bonded structure, the encapsulation layer 118′ can be provided with a material other than an adhesive material. For example, the encapsulation layer 118′ can be provided with a plurality of layers including at least one inorganic film and at least one organic film.

In addition, since the transparent display apparatus 100 according to another embodiment of the present disclosure does not have a bonded structure, the encapsulation film 200′ can be provided to cover the black matrix BM and the color filter CF. In the case of the transparent display apparatus according to FIG. 1, the substrate 110 and the opposing substrate 200 are manufactured separately and then bonded together, so the opposing substrate 200 can be made of a material with high rigidity so as to support the black matrix BM, the color filter CF, and the color pattern portion 120. In contrast, since the transparent display apparatus 100 according to another embodiment of the present disclosure has a COE structure rather than a bonded structure, the encapsulation layer 118′ can support the black matrix BM, the color filter CF, and the color pattern portion 120. Accordingly, a transparent display apparatus 100 according to another embodiment of the present disclosure can be provided with the encapsulation film 200′ having lower rigidity than the opposing substrate 200 on the black matrix BM and the color filter CF, thereby preventing oxygen or moisture from penetrating into the light-emitting element layer E.

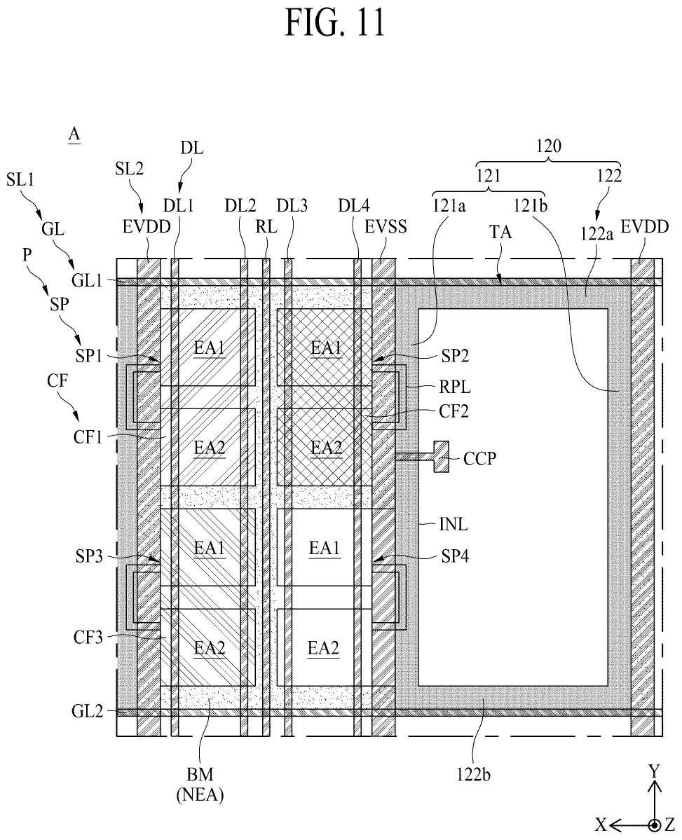

FIG. 11 is a plan view showing a transparent display apparatus according to another embodiment of the present disclosure.

Referring to FIG. 11, the transparent display apparatus 100 according to another embodiment of the present disclosure is the same as the transparent display apparatus according to FIG. 1 described above, except that the structure of the light emission area EA of each of the plurality of subpixels SP is changed. Therefore, the same drawing symbols have been assigned to the same configuration, and the different configurations will be described hereinafter.

In the case of the transparent display apparatus according to the above-described FIG. 1, each of the plurality of subpixels SP can be provided to include one light emission area EA. For example, as shown in FIG. 2, each of the first subpixel SP1, the second subpixel SP2, the third subpixel SP3, and the fourth subpixel SP4 can include one light emission area EA.

In contrast, in the case of the transparent display apparatus according to FIG. 11, each of the first subpixel SP1, the second subpixel SP2, the third subpixel SP3, and the fourth subpixel SP4 can include two light emission areas (EA1, EA2). For example, each of the first subpixel SP1, the second subpixel SP2, the third subpixel SP3, and the fourth subpixel SP4 can include a first light emission area EA1 and a second light emission area EA2 spaced apart from the first light emission area EA1. As shown in FIG. 11, the first light emission area EA1 and the second light emission area EA2 can be arranged spaced apart from each other in the second direction (Y-axis direction). Additionally, each of the first sub-pixel SP1, the second sub-pixel SP2, the third sub-pixel SP3, and the fourth sub-pixel SP4 can further include a repair line RPL connecting the first light emission area EA1 and the second light emission area EA2. The repair line RPL can be electrically connected to pixel electrodes arranged in each of the first light emission area EA1 and the second light emission area EA2. Additionally, the repair line RPL can be electrically connected to a thin film transistor that drives the subpixel SP. Accordingly, in the case of the transparent display apparatus according to FIG. 11, if a defect such as a dark spot occurs in one light emission area, the repair line RPL is cut so that the remaining light emission area can emit light normally. Therefore, the transparent display apparatus according to FIG. 11 can prevent the entire subpixel from not emitting light even if a dark spot defect occurs.

Meanwhile, the repair line RPL can partially overlap the transmissive area TA. This is to enable easy cutting of the repair line RPL when a dark spot occurs. A transparent display apparatus 100 according to another embodiment of the present disclosure can be provided such that the color pattern portion 120 covers the repair line RPL overlapping the transmissive area TA (in other words, a part of the repair line RPL overlapping the transmissive area TA). Accordingly, the transparent display apparatus 100 according to another embodiment of the present disclosure has a uniform shape of the transmissive area TA, so that the diffraction phenomenon does not occur, thereby improving the clarity of the background and/or the object.

Referring again to FIG. 11, in the transparent display apparatus 100 according to another embodiment of the present disclosure, the cathode contact portion CCP can be positioned close to the center of the transmissive area TA. This is to prevent moisture from penetrating into the light emission area EA through the cathode contact portion CCP. Accordingly, as shown in FIG. 11, the cathode contact portion CCP positioned close to the center of the transmissive area TA may not be covered by the color pattern portion 120. As a result, the transparent display apparatus 100 according to another embodiment of the present disclosure can have a structural feature in which the inner line INL of the color pattern portion 120 is positioned between the repair line RPL and the cathode contact portion CCP (or the cathode contact portion CCP positioned close to the center of the transmissive area TA).

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are examples in all respects and should be understood as non-limiting. The scope of protection of this disclosure shall be construed by the claims, and all technical ideas within the scope of the claims shall be construed to be included within the scope of the claims.

The transparent display apparatus according to aspects of the present disclosure can minimize or prevent yellowish color sensation of the background and/or the object by including the color pattern portion partially overlapping a transmissive area.

The transparent display apparatus according to aspects of the present disclosure can improve the clarity of an image and the background (and/or the object) by including the color pattern portion partially overlapping a transmissive area.

Since the transparent display apparatus according to aspects of the present disclosure can improve the clarity (or visibility) of an image due to the color pattern portion, it can have the same luminous efficiency or improve luminous efficiency more than that of a display apparatus without a color pattern portion even with low power consumption, so that the overall power consumption can be reduced.

The effects that can be obtained from the present disclosure are not limited to those mentioned above, and other effects not mentioned will be apparent to one having ordinary skill in the art from the following description.

What is claimed is:

1. A transparent display apparatus comprising:
a substrate provided with a plurality of pixels each having a plurality of sub-pixels;
a transmissive area provided on the substrate and arranged adjacent to at least some subpixels among the plurality of subpixels; and
a color pattern portion partially overlapping the transmissive area.

2. The transparent display apparatus of claim 1, wherein an area of the color pattern portion is provided at a ratio of 5% to 25% of an area of the transmissive area.

3. The transparent display apparatus of claim 1,
wherein the color pattern portion includes an inner line spaced apart from the plurality of subpixels, and
wherein the inner line has a straight line shape.

4. The transparent display apparatus of claim 1, wherein the color pattern portion includes at least one of a blue pattern portion, a red pattern portion, and a green pattern portion.

5. The transparent display apparatus of claim 1, further comprising:
an opposing substrate disposed on the substrate,
wherein the plurality of subpixels include a colored subpixel and a white subpixel disposed adjacent to the colored subpixel, and
wherein the color pattern portion is partially in contact with the opposing substrate between the white subpixel and the transmissive area.

6. The transparent display apparatus of claim 1, wherein the plurality of subpixels include:
a light emission area configured to emit light;
a non-light emission area arranged adjacent to the light emission area; and
a color filter arranged to overlap the light emission area,
wherein a thickness of the color pattern portion is thinner than a thickness of the color filter.

7. The transparent display apparatus of claim 6, wherein the transmittance of the transmissive area is inversely proportional to the thickness of the color pattern portion.

8. The transparent display apparatus of claim 1, further comprising:
a plurality of black matrices disposed between at least some subpixels of the plurality of subpixels and the transmissive area,
wherein the color pattern portion is partially overlapped with each of the plurality of black matrices or is disposed adjacent to each of the plurality of black matrices.

9. The transparent display apparatus of claim 1, wherein the color pattern portion is arranged along an edge of the transmissive area.

10. The transparent display apparatus of claim 1, wherein the color pattern portion is arranged in a square ring frame in the transmissive area.

11. The transparent display apparatus of claim 8,
wherein the substrate includes a plurality of gate lines arranged lengthwise in a first direction between the plurality of pixels,
wherein each of the plurality of black matrices is arranged lengthwise in a second direction intersecting the first direction, and
wherein the color pattern portion is partially arranged between the plurality of gate lines and between the plurality of black matrices.

12. The transparent display apparatus of claim 11, wherein the color pattern portion includes:
a plurality of first color pattern portions arranged in parallel along respective ones of the plurality of black matrices; and
a plurality of second color pattern portions connected to respective ones of the plurality of first color pattern portions and arranged in parallel along respective ones of the plurality of gate lines.

13. The transparent display apparatus of claim 12,
wherein the plurality of first color pattern portions are arranged spaced apart from a center of the transmissive area, and
wherein the plurality of second color pattern portions are arranged spaced apart from the center of the transmissive area.

14. The transparent display apparatus of claim 1, wherein the color pattern portion is arranged in a stripe shape in the transmissive area.

15. The transparent display apparatus of claim 14, further comprising:
a plurality of black matrices arranged between at least some subpixels of the plurality of subpixels and the transmissive area,
wherein the color pattern portion includes a plurality of first color pattern portions arranged in parallel along respective ones of the plurality of black matrices, and
wherein the plurality of first color pattern portions are arranged spaced apart from each other and from a center of the transmissive area in the first direction.

16. The transparent display apparatus of claim 8, wherein no black matrix is arranged between a white sub-pixel among the plurality of sub-pixels and the transmissive region.

17. The transparent display apparatus of claim 1, wherein the plurality of subpixels include:
a light emitting element layer arranged on the substrate;
a filling layer arranged on the light emitting element layer;
a black matrix arranged on the filling layer; and
a color filter arranged partially overlapping or adjacent to the black matrix, and
wherein a width of the color filter increases in an upward direction from the substrate toward the light emitting element layer.

18. The transparent display apparatus of claim 17, wherein a width of the black matrix increases in the upward direction.

19. The transparent display apparatus of claim 17,
wherein the color pattern portion is arranged on the filling layer together with the color filter, and
wherein a width of at least a portion of the color pattern portion increases in the upward direction.

20. The transparent display apparatus of claim 1, wherein the plurality of subpixels include:
a light emitting element layer arranged on the substrate;
an encapsulation layer arranged on the light emitting element layer;
a black matrix arranged on the encapsulation layer; and
a color filter arranged partially overlapping or adjacent to the black matrix,
wherein a width of the color filter decreases in an upward direction from the substrate toward the light emitting element layer.

21. The transparent display apparatus of claim 20, wherein a width of the black matrix decreases in the upward direction.

22. The transparent display apparatus of claim 20,
wherein the color pattern portion is arranged on the encapsulation layer together with the color filter, and
wherein a width of at least a portion of the color pattern portion decreases in the upward direction.

23. The transparent display apparatus of claim 20, further comprising:
an encapsulation film covering the black matrix and the color filter.

24. The transparent display apparatus of claim 1,
wherein the substrate includes a plurality of gate lines arranged lengthwise in a first direction between the plurality of pixels, and
wherein the color pattern portion partially covers each of the plurality of gate lines.

25. The transparent display apparatus of claim 1, wherein each of the plurality of sub-pixels includes:
a first light emission area;
a second light emission area spaced apart from the first light emission area; and
a repair line connecting the first light emission area and the second light emission area,
wherein the repair line partially overlaps the transmissive area, and
wherein the color pattern portion covers a part of the repair line that overlaps with the transmissive area.

26. The transparent display apparatus of claim 25,
wherein the substrate includes a cathode contact portion arranged close to a center of the transmissive area,
wherein the color pattern portion includes an inner line arranged spaced apart from the plurality of subpixels, and
wherein the inner line is arranged between the repair line and the cathode contact portion.
